(19) United States
(12) Patent Application Publication
(10) Pub. No.: US 2020/0256930 A1
(43) Pub. Date: Aug. 13, 2020

(54) CURRENT-SENSING METHOD OF GMI MAGNETIC FIELD MEASUREMENT

(71) Applicant: Spincoil Systems, Inc., Burlingame, CA (US)

(72) Inventor: Waldo Hinshaw, Burlingame, CA (US)

(21) Appl. No.: 16/708,347

(22) Filed: Dec. 9, 2019

Related U.S. Application Data
(60) Provisional application No. 62/803,996, filed on Feb. 11, 2019.
(60) Provisional application No. 62/834,896, filed on Apr. 16, 2019.

(51) Int. Cl. G01R 33/06

(52) U.S. Cl. CPC G01R 33/063

(57) ABSTRACT

Devices and methods for measuring the strength of a magnetic field are provided herein. A method as described herein may comprise providing a microwire and a coil, applying a magnetic field to the microwire such that the microwire has an initial magnetization, applying a drive current to the microwire, thereby inducing a coil current in the coil, determining the strength of the magnetic field based on the coil current through a low impedance shunt.

### CROSS-REFERENCE

This application claims the benefit of U.S. Provisional Application Nos. 62/803,996, filed Feb. 11, 2019 and 62/834,896, filed Apr. 16, 2019, which applications are incorporated herein by reference in their entirety.

### BACKGROUND

Magnetic field sensors, or magnetometers, are used in a wide range of applications. Magnetometers are used in fields such as agriculture, industry, national defense, biology, medicine aerospace, interplanetary research, video games, etc. They are also important components in all types of aircraft and spacecraft. A wide range of technologies are used in measuring magnetic fields including flux-gate, optically pumped, nuclear precession, Hall-effect, and inductive coils. Some of the existing technologies have to be shielded from Earth's field due to limited dynamic range. The ones that can operate in the presence of Earth's field have a limited ability to see very weak fields. Others involve complex technologies, or cannot operate at room temperature, are large, expensive, etc.

Since Superconducting Quantum Interference Devices (SQUIDs) were invented in 1964, researchers and clinicians have been using them to look at the magnetic fields generated by the electrical activity in both the brain and heart. Although providing a wide range of useful diagnostic information, there are relatively few clinical systems at the present time using SQUIDs. The equipment is expensive, the sensors have to be maintained at liquid helium temperature, and both the system and the patient have to be enclosed in an expensive magnetically shielded room.

The discovery of giant magnetoimpedance (GMI) in heterogeneous magnetic materials has resulted in a broad inquiry into the magnetoimpedance phenomena. Much of this research has been driven by the promise of sensitive magnetic field measurements. GMI technology is similar in some respects to Giant Magnetoresistance (GMR), the magnetic field sensing technology used in computer hard drives. GMI sensors are inherently inexpensive since they can be manufactured with integrated circuit equipment. Magnetic field sensors based on the GMI phenomenon have been developed for the compasses in cell phones. Although extremely sensitive, they have a wide range of applications since they operate at room temperature and in the presence of the Earth's magnetic field. Despite their wide range of use, GMI based magnetic sensors may be limited in bandwidth and speed. The voltage-based delay in such systems, may be problematic for fast varying data system since some valuable data may be lost in the time gap between measurements. Improved magnetic field sensors are therefore desired.

References of interest may include:
Panina, L. V., and K. Mohri. “Magneto-impedance effect in amorphous wires.” Applied Physics Letters 65.9 (1994): 1189-1191.
Beach, R. S., and A. E. Berkowitz. “Giant magnetic field dependent impedance of amorphous FeCoSiB wire.” Applied Physics Letters 64.26 (1994): 3652-3654.
Phan M-H, Peng H-X. “Giant magnetoimpedance materials: Fundamentals and applications”. Progress in Materials Science 53 (2008) 323-420.
Robbes, Didier. “Highly sensitive magnetometers—a review.” Sensors and Actuators A: Physical 129.1-2 (2006): 86-93.
Uchiyama, T., et al. “Recent advances of pico-Tesla resolution magneto-impedance sensor based on amorphous wire CMOS IC MI sensor.” IEEE Transactions on magnetics 48.11 (2012): 3833-3839.
Mohri, Kaneo, et al. “Recent advances of amorphous wire CMOS IC magneto-impedance sensors: Innovative high-performance micromagnetic sensor chip.” Journal of Sensors 2015 (2015).
Traoré, Papa Silly, Aktham Asfour, and Jean-Paul Yonnet. “Off-diagonal GMI sensors with a software-defined radio detector: Implementation and performance.” IEEE Transactions on Magnetics 53.4 (2016): 1-7.
Kanno, T., et al. “Amorphous wire MI micro sensor using C-MOS IC multivibrator.” IEEE Transactions on Magnetics 33.5 (1997): 3358-3360.
Mohri, Kaneo, et al. “Recent advances of amorphous wire CMOS IC magneto-impedance sensors: Innovative high-performance micromagnetic sensor chip.” Journal of Sensors 2015 (2015).
Kawajiri, N., et al. “Highly stable MI micro sensor using CMOS IC multivibrator with synchronous rectification [for automobile control application].” IEEE transactions on magnetics 35.5 (1999): 3667-3669.
Honkura Y, Yamamoto M, Koutani Y, et al. “Magnetic Sensor”. U.S. Pat. No. 7,026,812, United States Patent and Trademark Office, 11 Apr. 2006.
Yamamoto M, Arakawa H, Kawano T. “Magnetic Field Detecting Device”, U.S. Pat. No. 9,739,849B2, United States Patent and Trademark Office, 22 Aug. 2017.

### SUMMARY

Devices for measuring magnetic fields are provided herein. The embodiments of the disclosure can address at least some of the above limitations and deficiencies.

According to some aspects of the disclosure, a device for measuring a magnetic field is provided. The device may comprise at least one microwire, a coil and a low impedance shunt coupled to the coil wherein the device is configured to determine a strength of a magnetic field applied to the at least one microwire based on a coil current induced in the coil through the low impedance shunt by the at least one microwire.

The current may be induced in the coil in response to a drive current applied to the at least one microwire. In some embodiments, a plurality of microwires is provided. The coil may surround the microwires. In some embodiments, the coil has between 1 and 100 turns. The coil surrounding the microwire or microwires may comprise a wound foil.

In some embodiments, the coil surrounding the microwire or microwires comprises a pair of coils wound in opposing directions.

In some embodiments, the resistance of the low impedance shaft is less than 20 ohms.

In some embodiments, the device may comprise a current generator coupled to the at least one microwire. The current generator may apply a current to the at least one microwire that is a repeating current. The repeating current may be in the form of a discrete pulse or a sinusoid. The current generator may turn off the current to the at least on microwire before the coil current has decreased to half of its initial value.

The device may further comprise an amplifier coupled to the low impedance shaft configured to determine the current through the low impedance shunt. The device may further comprise a signal viewer coupled to the coil. The signal viewer may comprise an analog-to-digital convertor, a sample and hold circuit, or current integrator.

In some embodiments, the microwire may have a length of between 1 to 20 millimeters (mm). The microwire may have a radius between 1 and 30 microns. The microwire may be made of a magnetically soft ferromagnetic amorphous metallic alloy. The microwire may have a relative permeability of about 1 Henry per meter (H/m). The microwire may have nearly zero magnetostriction.

The device may further comprise a heat conducting element coupled to the microwire or microwires. The heat conducting element may be configured to convey heat away from the microwires. The heat conducting element may be a heat conducting gel.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the present disclosure are set forth with particularity in the appended claims. A better understanding of the features and advantages of the present disclosure will be obtained by reference to the following detailed description that sets forth illustrative embodiments, in which the principles of the present disclosure are utilized, and the accompanying drawings of which:

FIG. 1 shows a circuit diagram of a known opGMI sensor element.

FIG. 2 shows a graph of a voltage signal with a known opGMI sensor element.

FIG. 3 shows a graph of a current signal from an 80-turn coil of a known MPS sensor element. The drive-current stays on long enough to show the signal decay.

FIG. 4 shows a graph of a current signal from the 80-turn coil of an MPS sensor element, in accordance with some embodiments of the disclosure.

FIG. 5 schematically illustrates an example of a sensor element, in accordance with some embodiments of the disclosure.

FIG. 6 shows a circuit diagram of an exemplary electrical circuit, in accordance with embodiments of the disclosure.

FIG. 7 shows a perspective view of an exemplary coil constructed with foil instead of wire, in accordance with embodiments of the disclosure.

FIG. 8 shows a top view of the foil used in the coil of FIG. 7, in accordance with embodiments of the disclosure.

### DETAILED DESCRIPTION

Current technology used for measuring magnetic fields may rely on measuring voltage changes due to a magnetic field in a magnetic material such as a microwire. In order to allow for the voltage changes of such circuitry to return to equilibrium, there may be a delay of a few microseconds (μsec) between consecutive measurements. This delay between measurements may cause a loss of signal as well as degradation of signal to noise ratio. Measuring the magnetic field more frequently (more times per second) may increase the signal to noise ratio per unit time. Furthermore, in rapidly changing systems, the delay between measurements may cause loss of important data.

The embodiments of the disclosure described herein can enable improved measurement of magnetic fields which in turn may improve the quality of the measurements such as signal to noise ratio in a given signal acquisition time or may increase the bandwidth.

Drive-currents can have different forms, for example be a sinusoidal, square wave, or other time-dependent function. The methods and devices provided herein may provide enhanced signal to noise ratio over previous voltage-based measurement methods. The disclosed methods may further reduce the frequency limitations of a tank circuit. The coil designed for voltage-sensing with many turns and its parasitic capacitance may form a self-resonant circuit, even if no capacitance is added. The ringing of this tank circuit after a drive pulse may limit how soon the next drive pulse can be applied.

Methods presented herein may enable shorter durations of drive-current flowing in the microwire and therefore may result in less heat deposited in the microwire. This may lead to simpler heat management schemes and more efficient performance of the circuitry.

The observable frequency bandwidth of the applied magnetic field in the voltage-sensing methods may be limited by the repetition rate of the measurements. The methods described herein may allow the magnetization to be sampled much more frequently making it sensitive to much higher frequency components of the applied magnetic field. The methods and devices described herein may improve the measurement sensitivity by averaging more measurements per unit time.

The voltage-sensing methods are highly dependent upon the properties of the coil self-resonance and the properties of the coil's tank-circuit. For example, with the prior art opGMI method, the time required for the signal voltage to reach its maximum may depend upon properties of the coil and its associated capacitance. The methods and devices described herein may not be dependent upon the properties of a tank circuit.

The early prior art giant magnetoimpedance (GMI) is related to large impedance changes in a material due to application of an external magnetic field to that material. Since this prior art method observes the change in the impedance of the microwire, it is usually referred to as diagonal GMI and will be denoted herein as dGMI. The heterogeneous magnetic materials used for dGMI may typically be in the form of a “microwire” with a diameter between 10 and 30 microns. The diameter of the microwire may be smaller than 10 microns. In some instances, the diameter of the microwire may be larger than 30 microns. The microwire may comprise a single microwire or a plurality of microwires. The microwire material may be a magnetically soft amorphous alloy with nearly zero magnetostriction. The magnetic permeability may be very high, typically close to unity. When a high-frequency alternating current, the “drive-current” is passed through the magnetic material, the electrical impedance of the material increases dramatically (hence the term “giant”) when the material is exposed to a magnetic field in the direction of the microwire. The commercially available microwire used for dGMI may be composed of an amorphous magnetic material that has been rapidly cooled from the melt into a metallic glass and often post-processed to create large internal stresses.

The increase in magnetization of the material caused by the applied magnetic field to the magnetic material may cause a decrease in the skin-depth in which a high-frequency current is constrained. This reduction in the cross-section through which the current flows, results in an increase in the electrical impedance. An alternative explanation might be that the reorientation of the magnetization caused by the applied field may increase the scattering of the electrons in the magnetic material thus impeding the flow of current.

The dGMI phenomenon may be observed by passing a high-frequency alternating current, herein referred to as the “drive-current”, through the microwire and observing the dependence of the microwire's impedance on the strength of the magnetic field in the direction of the microwire. The drive-current amplitude may be constant. The voltage across the ends of the microwire may be a measure of the strength of the magnetic field in the direction of the microwire in this arrangement.

Several modifications of the dGMI method of measuring magnetic fields have been developed previously. In one modification, the impedance of the microwire may be monitored while applying rapid pulses of current rather than alternating current. The impedance may increase regardless of the direction of the magnetic field with respect to the microwire and regardless of the direction of the drive-current.

In another GMI method, hereinafter referred to as “off-diagonal GMI”, a coil of wire may surround the microwire and the strength of the alternating voltage from the coil may be observed while a high-frequency alternating current is applied to the microwire. Although this method is usually referred to as a GMI method, the change in diagonal impedance may not be directly involved and the physics involved in generating the signal may be different.

Another existing variation of the technique may combine the above-mentioned methods by surrounding the microwire with a coil of wire and observing the voltage signal from the coil when pulses of current are applied to the microwire. This method is referred to herein as the opGMI method for “off-diagonal pulsed GMI”. One advantage of the off-diagonal methods over the diagonal methods may be that the polarity of the observed signal depends upon the direction of the magnetic field with respect to the winding direction of the coil surrounding the microwire, whereas the polarity of the observed signal with the diagonal methods may be independent of the magnetic field direction.

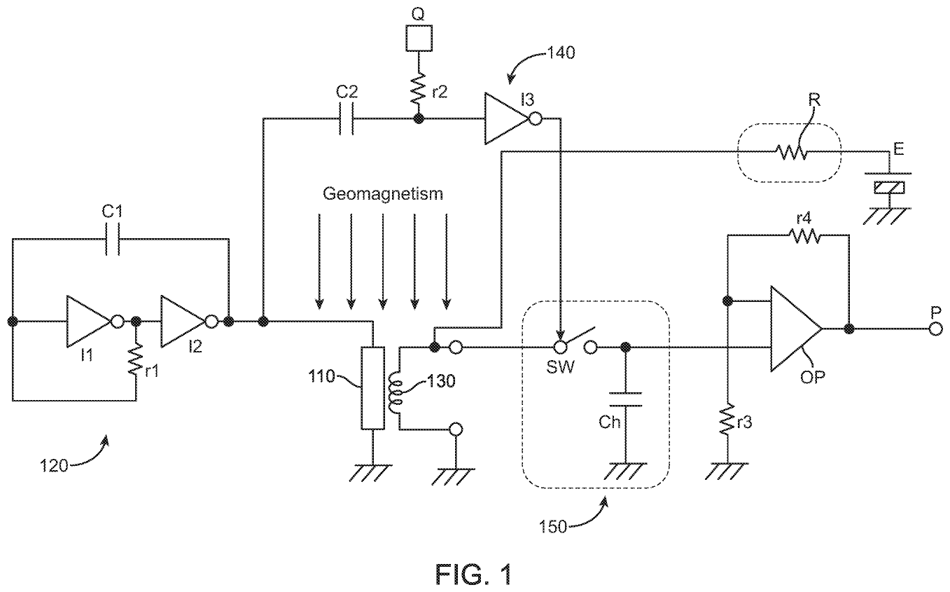

An example of the existing opGMI methods is shown in FIG. 1 (Yamamoto et. al. U.S. Pat. No. 9,739,849). This circuit provides an analog output at P. The output may be proportional to the field at the microwire 110. The circuit elements 120 provide a repeating square wave current pulse that goes through the microwire 110. This initial pulse also goes to the circuit elements 140 which delay the initial pulse providing a second, delayed, pulse. This delayed pulse is timed to turn on the switch SW when the signal voltage out of the coil 130 reaches its maximum. This switch SW and the capacitor Ch, together indicated as 150, function as a sample-and-hold circuit. The voltage in capacitor Ch is output at P by the operational amplifier OP. This circuit may also apply an additional current, provided by voltage source E and resistor R, to the coil 130. This provides an additional magnetic field to the microwire 110 and is intended to counteract the Earth's magnetic field.

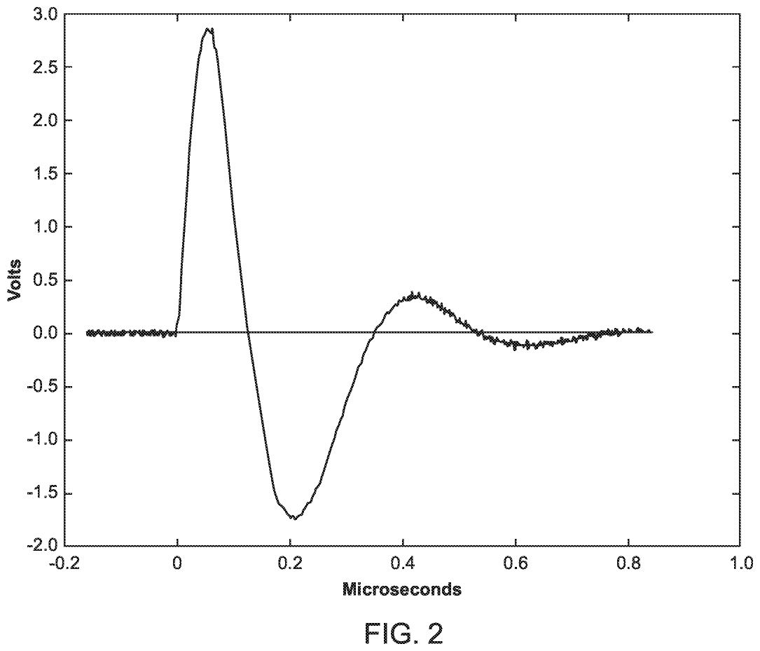

FIG. 2 shows an example of an output signal of an opGMI sensor element, such as the one shown in FIG. 1. In the example of FIG. 2 the voltage from the coil is shown as a function of time. When the drive-current turns on at time t=0, the voltage across the coil starts rising. When it reaches its maximum, a sample-and-hold circuit samples the voltage. After the signal is sampled, the drive-current is turned off. In the example of FIG. 2, the drive-current is turned off 45 ns after it was turned on. The plot shows the ring-down of the voltage after the drive-current is off. The next pulse of drive-current is not applied until the signal rings down and the microwire regains its equilibrium magnetization with the applied field. The minimum delay between one drive-current pulse and the next is typically between one and five microseconds.

The ringing may be due to the tank circuit formed by the coil and its parasitic capacitance and any capacitance added by the subsequent circuitry. The rapid damping of the ringing may be due to the resistance of the coil, resistive loading of subsequent circuitry, as well as the energy absorbed by the microwire as the tank circuit rings. In order to maximize the voltage, coils with many turns may be used. In the example of FIG. 2 the coil had about 300 turns.

The efficiency of measurements may be limited in opGMI technology. The microwire may regain its equilibrium magnetization with the applied magnetic field in less than a nanosecond. However, as described elsewhere herein, at least a microsecond may be needed between repetition of measurements. The loss of signal per unit time may be at a factor of thousand or larger.

As described herein, methods and devices for measuring the strength of magnetic fields are disclosed. In one embodiment the methods may comprise providing a microwire and a coil, applying a magnetic field to the microwire such that the microwire has an initial magnetization, applying a drive current to the microwire, thereby inducing a coil current in the coil, determining the strength of the magnetic field based on the induced coil current through a low impedance shunt.

Embodiments of the present disclosure may include methods of briefly switching the magnetic permeability of the microwire to a reduced value and observing the current generated in the surrounding coil. For convenience, the methods disclosed herein may be denoted “magnetic permeability switching”, or “MPS”.

In some embodiments of the disclosure, when the drive-current is turned on, and as the voltage across the coil is starting to increase from zero, the current out of the coil may already be at its maximum. By measuring the current rather than the voltage, the measurement can be made without waiting for the signal voltage to increase to its maximum. Furthermore, turning off the drive-current while the coil current is still high may cause the microwire magnetization to be restored to the value it had before the drive-current started. This, in turn, can cause the coil current to stop flowing so that the coil current goes back to zero. This may allow the measurement to be repeated without significant delay and without waiting for a ring-down of the coil voltage (such as the ring down shown in example of FIG. 2).

When the microwire is in equilibrium with a magnetic field applied in the axial direction of the microwire, (hereinafter referred to as the “applied field”), the microwire may be magnetized axially, in the direction along its length. The microwire may have a high magnetic permeability. Magnetic permeability can be defined as the degree of magnetization of a material in response to the applied magnetic field. The magnetic permeability of the microwire may be about 1 Henry per meter (H/m). In some embodiments, the magnetic permeability of the microwire may be larger or smaller than 1 H/m. The microwire may be made of magnetically soft material such as a metallic alloy. The metallic alloy used in the microwire may be an amorphous metallic alloy. Nonlimiting examples of magnetically soft amorphous metallic alloys used in microwires may include Cobalt-rich alloys such as Co67Fe3.85Ni1.45B11.5Si14.5Mo1.7 or iron-rich ferromagnetic amorphous alloys. The magnetically soft microwire may have nearly circular magnetic anisotropy. The microwire may comprise a plurality of microwires.

As the drive-current flows through the microwire, the permeability of the microwire may be reduced. As the drive-current flows through the microwire, it may create a strong circular magnetic field in and near the surface of the wire. This additional circular magnetization may be strong enough to reorient the magnetic domains near the surface so that their magnetically soft direction may no longer be oriented axially. This may cause the axial permeability to decrease and thus may cause the microwire to eject some of its flux. The coil may surround the microwire and/or be coaxial with the microwire. In this case, as the ejected flux leaves the microwire, it may cross the coil windings and, in doing so, may induce current in the windings according to Faraday's law of induction. Determining the strength of the magnetic field may comprise switching the microwire between a first magnetic permeability and a second magnetic permeability different from the first magnetic permeability and observing the induced coil current.

The coil may have between one and 100 turns. In some instances, the coil may have more than 100 turns. The amount of flux leaving the microwire, and thus the coil current, may be related to the initial magnetization of the microwire which, in turn, may be related to the magnetic field applied to the microwire. The coil current may be related to, and/or proportional to, the strength of the magnetic field in the direction of the microwire just before the drive-current starts. The coil current through a low impedance shunt can be a measure of the strength of the applied magnetic field.

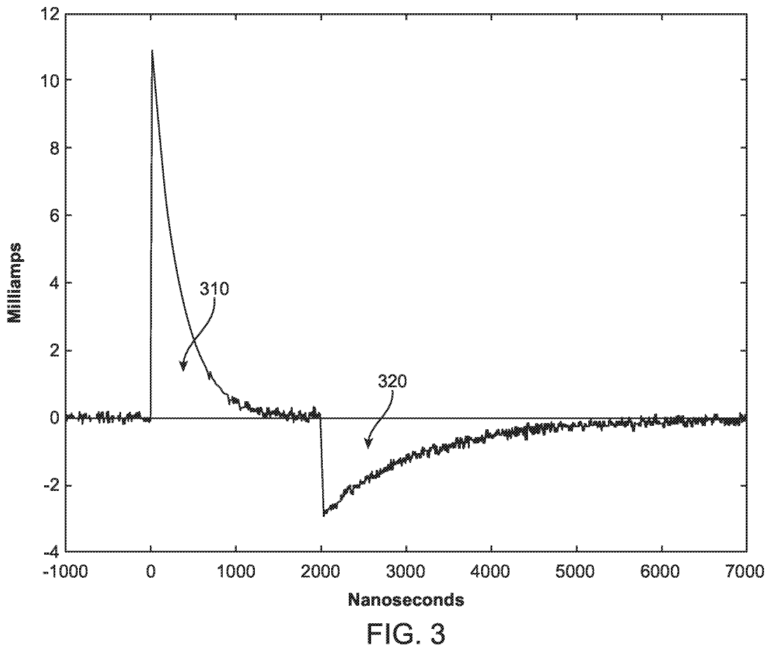

FIG. 3 shows an example of the coil current as a function of time as produced by some embodiments. In this example the coil current increases quickly at t=0, roughly as fast as the turn-on of the drive-current.

If the coil surrounding the microwire were to be superconducting with its ends connected together, it would keep the ejected flux contained within the coil by its induced current. For a coil and its termination that are resistive, the current induced in the coil when the drive-current turns on decays exponentially, as shown in example of FIG. 3. The time constant τ for the exponential decay, is given by τ=L/R wherein L is the inductance of the coil (inductance of empty coil multiplied by the effective permeability of the microwire) and R is the resistance of the set of coil and its related shunt.

In some embodiments, the coil surrounding the microwires may be attached to a low impedance shunt. The shunt can be a resistor, transimpedance amplifier, or other circuit element that has a low input impedance.

The strength of the exponentially decaying coil current may be proportional to the difference in the magnetic field strengths, or flux densities, between the inside and the outside of the coil. The amount of flux ejected by the drive-current may be proportional to, inter alia, the strength of the applied field and/or the permeability change of the microwire.

As long as the drive-current is maintained in the microwire, its permeability may be held low and the ejected flux may be locked out of the microwire. According to Lenz's law, the induced current in the coil tries to maintain the flux within the coil. As long as the coil current is maintained, the excluded flux may be confined inside the coil.

In the example of FIG. 3, the drive current is held on for 2 microseconds, in which time the coil current is decreased to near zero. At that point, the flux densities inside and outside the coil are equivalent. The permeability of the microwire may increase to its earlier value after the drive-current is turned off. As the flux comes back into the microwire, it may cross the coil again inducing current in the coil, but with the reverse sign. In the example of FIG. 3, the areas 310 and 320 under the curve of current versus time may be equal.

The leading exponential part of the curve (310) in FIG. 3 may have a shorter time constant than the trailing exponential part of the curve (320), which agrees with the method of the disclosure, i.e. the permeability of the microwire may be reduced when the drive-current is on. The reduced permeability may result in lower coil inductance which, in turn, may result in a shorter exponential decay. The change in the effective permeability of the microwire can be calculated from the observed decay time constants. The drive-current may be applied as a discrete pulse. The drive-current may be applied for at least 1 nanosecond. The drive-current may be applied for 1, 2, 5, 10, 20, 50, 100, 200, 300, 400 or 500 ns or any value in between. In some embodiments, the drive-current may be applied for less than one ns. In some embodiments, the drive-current may be applied for longer than 500 ns.

In the example of FIG. 3, the drive-current remained on long enough for the coil current to reach near zero.

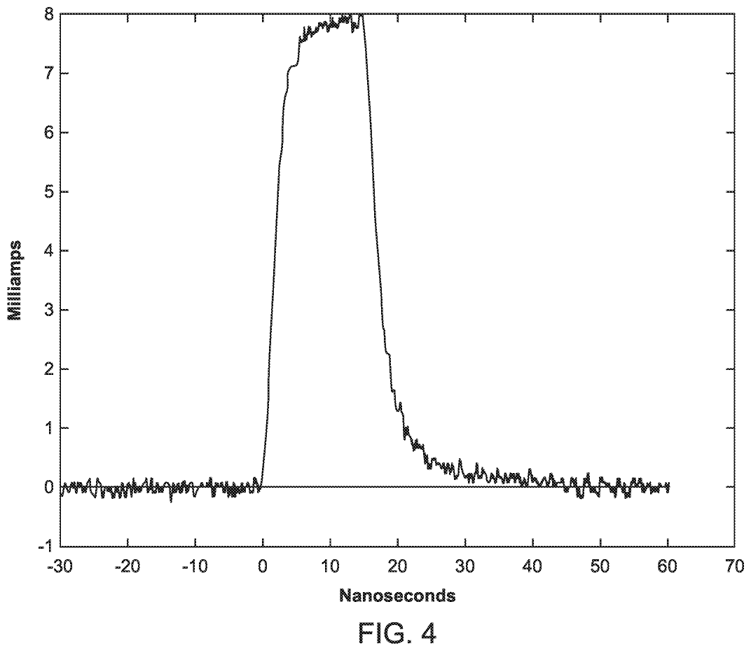

In the example of FIG. 4, the drive-current is turned off while the coil current is still at or near its maximum. In this case, most of the flux may remain in the coil and may not have enough time to escape from the coil. When the drive-current stops, the dense lines of flux trapped inside the coil may quickly be absorbed back into the microwire. Once the flux held inside the coil goes back into the microwire, the flux densities inside and outside the coil may again become the same as before the drive-current started. As a result, the coil current may go back to zero. The short drive-current pulse turns on the coil current so that it can be measured and then turns it back off again.

The flow of drive current may cause the microwire to heat up. With the prior art voltage-sensing methods, there is time between drive pulses during which the microwire may cool. With the herein described current-sensing method, the drive pulses may be applied with very little time between them. Since each drive pulse deposits heat in the microwire, it may be advantageous to have a means for removing some of the heat. In some embodiments, the microwire may be immersed in a heat conducting gel as described elsewhere. Some embodiments of the disclosure may include an element for removing heat from the microwire such as a heat conducting gel or a heat sink. Nonlimiting examples of heat removing element may include a flowing heat-conducting fluid in the proximity of microwire. The heat may be removed by blowing air to the circuit and microwires using for example a fan. The heat conducting element may be a coating covering parts of the circuit such as the microwires or the coil. The heat sink may be coupled to at least one microwire.

Low resistance of the coil with its shunt may allow for the current to persist long enough to be measured. The impedance of the shunt may be smaller than 15 ohms. In some embodiments, the resistance of shunt may be equal to or larger than 15 ohms. The method of the present disclosure may eliminate the need for having a coil with large number of turns since the measurements are done based on current and not the voltage. In the case of voltage-based measurements, the equivalent impedance may be large.

As described herein, methods and devices for measuring magnetic fields are disclosed. In one embodiment the device may comprise at least one microwire, a coil and a low impedance shunt coupled to the coil, wherein the device is configured to determine a strength of a magnetic field applied to the at least one microwire based on a coil current induced in the coil through the low impedance shunt by the at least one microwire. In some embodiments, the coil current may be induced in the coil in response to a change in magnetic permeability of the at least one microwire.

As described herein, methods and devices for measuring strength of magnetic field are disclosed. In one embodiment, a magnetic field sensor based on giant magnetoimpedance phenomenon is provided. The magnetic field sensor may comprise at least one microwire, a heat conducting element coupled to the at least one microwire and configured to convey heat away from the at least one microwire, and a processor coupled to the at least one microwire and configured to determine a strength of a magnetic field applied to the at least one microwire based on a change in one or more of an impedance, a voltage, a current, or a magnetic permeability of the at least one microwire in response to the applied magnetic field. The change in the one or more of the impedance, the voltage, the current, or the magnetic permeability may be detected by a coil in proximity of or coupled to the at least one microwire. The change in the one or more of the impedance, the voltage, the current, or the magnetic permeability also may be detected by measurement of the at least one microwire.

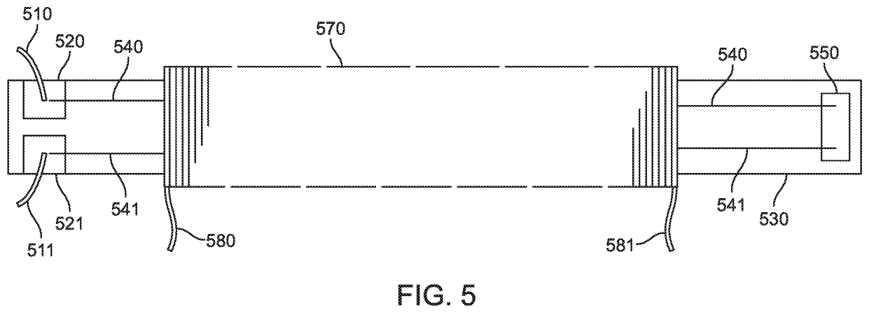

FIG. 5 shows an example of a sensor element for measuring magnetic fields in accordance with some embodiments. The drive-current may pass through the microwire with wires 510 and 511.

These wires may be connected to the conducting pads 520 and 521 which may be mechanically attached to the support structure 530. The two microwires 540 and 541 may be connected to the conducting pads 520 and 521 at one end and both may be connected to the conducting pad 550 at their other ends. The conducting pad 550 may not be mechanically attached to the support structure 530 in order to prevent the microwires from being stressed when their length changes due to for example heating. The two microwires may be supported on the support structure 530 but not attached mechanically. The microwire may have a length of between 5 to 15 mm. The length of microwire may be smaller than 5 mm. In some embodiments, the length of microwire may be larger than 15 mm. The radius of microwire may be between 5 and 30 microns. The radius of microwire may be smaller than 5 microns. In some embodiments, the radius of microwire may be larger than 30 microns. In case there is a plurality of microwires in the circuit, all or a subset of microwires may have equal radii. In case there is a plurality of microwires in the circuit, each of them may have a different radius. The microwires may have a cross-sectional area of between 78.5 and 2826 square microns. The cross-sectional area of microwire may be smaller than 78.5 square microns. The cross-sectional area of microwire may be larger than 2826 square microns.

This assembly may be surrounded by the coil 570. The coil 570 may have connecting wires 580 and 581 that are both connected to the shunt. The coil may be made of copper, gold, silver or other conductors. The microwires 540 and 541 may be imbedded in a protective gel which also fills the coil 570. This gel can have high thermal conductivity, such as a heat-sink compound, in order to help remove the heat from the microwires.

Having multiple microwires that are attached at only one end might be advantageous. If there is only a single microwire attached at both ends, it may induce stress when heated. The generation of an axial magnetic field by the drive current in the microwires may be reduced if the drive current flows in both directions and the microwires are located close to each other. If the magnetic field from the drive current has an axial component, the field may couple with the surrounding coil and may cause erroneous results.

In one example, the microwires may have 83 turns of insulated AWG 42 copper wire. In the aforementioned example, the coil may have a cross-sectional area of about 0.4 square millimeters. The geometry of the sensor element and the arrangement of the leads may be adjusted in order to minimize the coupling of any axial field generated by the drive-current into the coil.

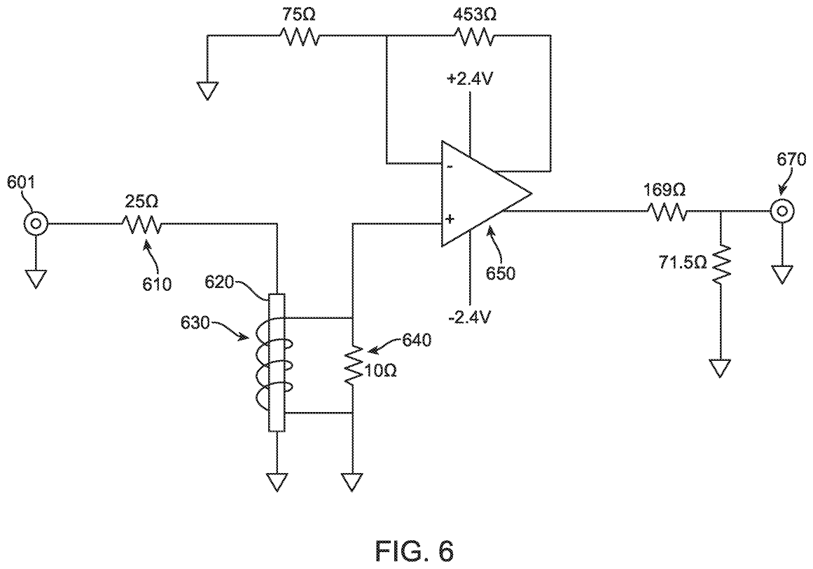

FIG. 6 shows an example of the electronic circuitry used in some embodiments. The drive-current is introduced at connector 601. The drive-current may be provided by a pulse generator coupled to at least one microwire. A nonlimiting example of pulse generator is an SRS model DG645 pulse generator which provides a square wave pulse with rise and fall times of 1 ns and with controllable voltage and duration. A resistor 610 may be in series with the microwire 620 so that the input provides a 50-ohm load to the pulse generator. Resistor 610 may have a value of about 25 ohms. The microwires 620 are surrounded by the coil 630 which is connected to the shunt resistor 640. The shunt resistor may have a small value of for example between 10 and 15 ohms. The coil may be coupled to an amplifier. The output of the coil and its shunt resistor may go into the operational amplifier (opAmp) 650. A nonlimiting example of amplifier 650 can be a Texas Instruments OPA858 operational amplifier which has a CMOS input and a 5.5 GHz gain bandwidth product. The opAmp may be configured to have a gain of unity. The two feedback resistors can be changed to give higher gain. The output 670 of the circuit can be connected to an oscilloscope or other device for observing the signal. The coil may be coupled to a signal viewer comprising an analog-to-digital converter, a sample and hold circuit or a current integrator.

The example circuit of FIG. 6 shows how the applied magnetic field can be measured by looking at the current out of the coil rather than the voltage. When the drive-current is a short pulse, the coil may produce a pulse of current. The strength of the produced current pulse may be a measure of the strength of the applied field. If a more continuous output is required, the circuit shown in FIG. 6 may be followed with a sample-and-hold means and other signal handling circuit as required. Further, if digital output is required, an analog-to-digital converter may also be included in the circuitry.

Various configurations of the microwire and/or other configurations of the coil as well as other variations of the circuitry can be envisioned that follow the methods and devices of the present disclosure. Other circuits may provide current-sensing of the signal from the coil. For example, the shunt resistor and opAmp may be replaced with a transimpedance amplifier that presents a very low impedance to the coil. The transimpedance amplifier might be well suited for measuring the current from a small sensor element that produces small currents. The circuit also can be configured to integrate the current over all or part of the signal pulse from the coil rather than the sample-and-hold means mentioned above.

The example of FIG. 6 may be designed for use with discrete pulses of drive-current, but it can also work with sinusoidal drive-currents. However, if used with sinusoidal drive-currents, rather than following the circuit of FIG. 6 with a sample-and-hold means, analog circuitry can be used. The processing of the AC signal from such a current-sensing AC method may be similar to that described in the prior art literature for the voltage-sensing AC methods. The alternating current, or AC, may be the same as applying the drive-current pulses described above with the interval between pulses approximately the same as the pulse widths. When the AC current is offset with an added DC component, the resulting drive current may be similar to a close-together series of pulses. The permeability modulation phenomenon described above may produce a current in the coil in the same way.

As described elsewhere, the inductance of the coil and the resistance of the coil and shunt may determine the exponential decay time constant of the current signal from a long drive-current pulse. Any combination of values for the inductance and resistance may be used as long as the decay time of the current is long enough to make the measurement. If the AC current-sensing method is used, the decay time may be long compared to the drive-current cycle time.

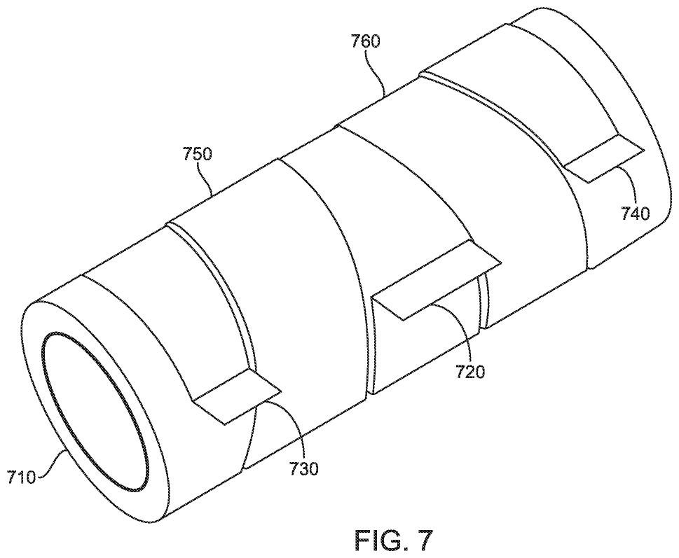

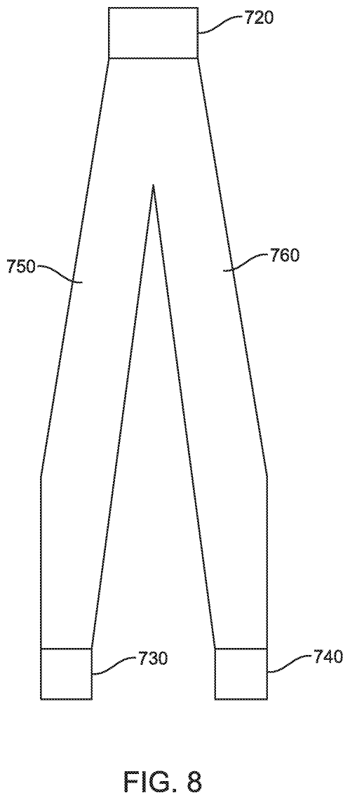

The coil can be formed with a conductor that does not have a circular cross section. For example, copper foil may be used in order to keep the resistance low and to improve the removal of heat from the microwire. FIG. 7 is an example of a coil constructed with foil rather than wire. The current may increase as the number of turns decreases. In the example of FIG. 7 the coil has four turns. The number of turns may be less than 4. In some embodiments, the number of turns may be more than 4. With few turns, the inductance may be low requiring a very low resistance shunt such as the effectively zero input impedance of a transimpedance amplifier. The coil of FIG. 7 may be wound of copper foil on the cylinder 710. The coil may be symmetrically wound with a center tap, 720, that can be connected to the shunt to circuit ground while the other two ends of the coil, 730 and 740, can be connected to the circuit ground. The approximate centers of the two turns on each side are at 750 and 760. This center-tap design is not the same as the usual center-tap coil design where the windings go in the same direction on both sides of the center. In the design described herein, the windings may go in opposite directions on the two sides of the center-tap. This means that escaping flux may induce a current in the opposite directions in the two sides, either toward the center or toward the ends. This “reversed” center-tap design may also be used when wire instead of foil is used as the conductor. The advantages of this symmetric, center-tap, coil design may include the following aspects: The two coils in parallel may reduce the coil's resistance. The foil covering the surface of the cylinder may be more effective than wire in containing the flux ejected from the microwire. The symmetric design with the current flow going in opposite axial directions in the two ends of the coil may be less sensitive to the magnetic field arising from the drive-current. A coil wound in a single axial direction may have a net axial component that can couple with the circular field generated by the microwire's drive-current. This coupling may result in a spurious transient, offset, or other error in the observed signal from the coil. The shape of the foil for this coil design is shown in FIG. 8.

While preferred embodiments of the present disclosure have been shown and described herein, it will be obvious to those skilled in the art that such embodiments are provided by way of example only. Numerous variations, changes, and substitutions will now occur to those skilled in the art without departing from the scope of the present disclosure. It should be understood that various alternatives to the embodiments of the present disclosure described herein may be employed in practicing the invention(s) of the present disclosure. It is intended that the following claims define the scope of the invention and that methods and structures within the scope of these claims and their equivalents be covered thereby.

What is claimed is:

1. A device for measuring a magnetic field, the device comprising:
at least one microwire;
a coil; and
a low impedance shunt coupled to the coil,
wherein the device is configured to determine a strength of a magnetic field applied to the at least one microwire based on a coil current induced in the coil through the low impedance shunt by the at least one microwire.

2. The device of claim 1, wherein the coil current is induced in the coil in response to a drive current applied to the at least one microwire.

3. The device of claim 1, wherein a plurality of the microwires is provided.

4. The device of claim 1, wherein the coil surrounds the at least one microwire.

5. The device of claim 1, wherein the coil has between 1 and 100 turns.

6. The device of claim 4, wherein the coil surrounding the at least one microwire comprises a wound foil.

7. The device of claim 4, wherein the coil surrounding the microwire comprises a pair of coils wound in opposing directions.

8. The device of claim 1, wherein the low impedance shunt has a resistance lower than 20 ohms.

9. The device of claim 1, further comprising a current generator coupled to the at least one microwire.

10. The device of claim 9, wherein the current generator applies a current to the at least one microwire that is a repeating current.

11. The device of claim 10, wherein the repeating current is in the form of a discrete pulse.

12. The device of claim 10, wherein the repeating current is in the form of a sinusoid.

13. The device of claim 10, wherein the current generator turns off the current to the at least one microwire before the coil current has decreased to one half of its initial value.

14. The device of claim 1, further comprising an amplifier coupled to the low impedance shunt configured to determine a current through the low impedance shunt.

15. The device of claim 1, further comprising a signal viewer coupled to the coil.

16. The device of claim 15, wherein the signal viewer comprises an analog-to-digital convertor, a sample and hold circuit, or a current integrator.

17. The device of claim 1, wherein the microwire has a length of between 1 to 20 millimeters (mm).

18. The device of claim 1, wherein the microwire has a radius of between 1 and 30 microns.

19. The device of claim 1, wherein the microwire is made of a magnetically soft ferromagnetic amorphous metallic alloy.

20. The device of claim 1, wherein the microwire comprises a relative permeability of about 1 Henry per meter (H/m).

21. The device of claim 1, wherein the microwire has nearly zero magnetostriction.

22. The device of claim 1, further comprising a heat conducting element coupled to the at least one microwire and configured to convey heat away from the at least one microwire.

23. The device of claim 22, wherein the heat conducting element comprises a heat conducting gel.
